(19) United States
(12) Patent Application Publication
(10) Pub. No.: US 2014/0230869 A1
(43) Pub. Date: Aug. 21, 2014

(54) Self-Powered Boiler Using Thermoelectric Generator

(71) Applicant: GMZ Energy, Inc., Waltham, MA (US)

(72) Inventors: Gang Chen, Carlisle, MA (US); Yanliang Zhang, Framingham, MA (US); James Christopher Caylor, Melrose, MA (US); Jonathan D'Angelo, Somerville, MA (US); Xiaowei Wang, Chestnut Hill, MA (US)

(73) Assignee: GMZ Energy, Inc., Waltham, MA (US)

(21) Appl. No.: 14/182,475

(22) Filed: Feb. 18, 2014

Related U.S. Application Data
(60) Provisional application No. 61/766,300, filed on Feb. 19, 2013.

(51) Int. Cl. H01L 35/32

(52) U.S. Cl. CPC H01L 35/325
USPC 136/201; 136/208

(57) ABSTRACT

A self-powered boiler comprising a burner that burns a fuel to produce a hot combustion product that is used to heat a fluid and a thermoelectric generator (TEG) system comprising a first side in thermal communication with the hot combustion product and a second side in thermal communication with a lower temperature region of the boiler, and a plurality of thermoelectric converters disposed therebetween for generating electric power, wherein the electric power generated by the TEG system is equal to or greater than a total electric power consumed by the boiler under normal operating conditions.

### RELATED APPLICATIONS

This application claims the benefit of priority to U.S. Provisional Application No. 61/766,300 filed on Feb. 19, 2013, the entire contents of which are incorporated herein by reference.

### BACKGROUND

Thermoelectric converters, such as solar thermoelectric converters are known in the art. These converters rely upon the Seebeck effect to convert temperature differences into electricity. A portion of the thermoelectric converter may be directly or indirectly heated by a heat source to create the necessary temperature difference. The efficiency of the energy conversion depends upon the temperature difference across the thermoelectric converter and the thermoelectric material's figure of merit, ZT. Greater temperature differences and greater ZT allow for greater conversion efficiency.

### SUMMARY

Embodiments may include a self-powered boiler comprising a burner that is adapted to burn a fuel to produce a hot combustion product, a hot combustion product conduit, and a thermoelectric generator (TEG) system comprising a first side in thermal communication with the hot combustion product conduit and a second side in thermal communication with a lower temperature region of the boiler, and a plurality of thermoelectric converters disposed therebetween, the thermoelectric converters comprising a nano structured thermoelectric material, wherein electric power generated by the TEG system is equal to or greater than a total electric power consumed by the boiler under steady state operating conditions.

Further embodiments include methods of operating a self-powered boiler comprising burning a fuel to produce a hot combustion product, flowing the hot combustion product in thermal contact with a first side of a thermoelectric generator (TEG) system comprising a nanostructured thermoelectric material, and generating electrical power by the TEG system that is equal to or greater than a total electric power consumed by the boiler under steady state operating conditions.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1A is a schematic cross sectional side view of a boiler having a plurality of thermoelectric power generators (TEG) according to one embodiment.

FIG. 1B is a cross-section view of the boiler of FIG. 1A taken along line A-A.

FIG. 2 is a perspective view of a boiler illustrating the location of a thermoelectric generator system according to one embodiment.

FIG. 3 is a perspective view of a design of a heat exchanger and thermoelectric generator for a boiler.

FIG. 4 illustrates simulation results for the heat exchanger and thermoelectric generator of FIG. 3.

FIG. 5 is cross sectional perspective view of a gradient heat exchanger with an increasing pin fin packing faction along the direction of fluid flow.

FIG. 6 is a cross-sectional perspective view of a gradient heat exchanger with an increasing plate fin packing fraction along the direction of fluid flow.

FIG. 7 schematically illustrates a boiler having a heat exchanger unit and a burner unit having a plurality of TEG modules integrated into the burner unit.

FIG. 8A schematically illustrates a self-powered boiler according to an embodiment.

FIG. 8B illustrates a thermoelectric generator module with integrated heat exchanger.

### DEAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

Multiple methods exist for generating electricity from heat energy. Various embodiments may include thermoelectric conversion elements. Thermoelectric conversion relies on the Seebeck effect to convert temperature differences into electricity. Thermoelectric converters operate more efficiently under greater temperature differences.

Boilers are widely used to heat buildings and generate hot water. A boiler typically operates by combusting a fuel to heat water or another fluid. Operation of a boiler typically requires consumption of a certain amount of electric power to drive various components of the boiler system, such as a control unit, fan(s) or blower(s) (e.g., air or fuel), pumps, electrically actuated valves, etc. In some cases, the boiler may provide local (i.e., space) heating, in other cases the boiler may provide domestic hot water heating and/or one or more heating circuits via a header and control valves. The operating temperature and flow rates of the system may vary depending on the size and type of the heating system, as well as the type of heat emitter(s) utilized (e.g., radiator, radiant floor, fan coil-type, etc.).

The largest amount of power consumption in a boiler-based heating system is typically attributable to the pump or pumps used to displace a fluid medium (e.g., water) of the heating system through a heat exchanger in thermal contact with the hot combustion products of the boiler flame and to provide the heated fluid medium to a location external to the boiler for subsequent use. The pump may be responsible for upwards of half of the total power consumption of the boiler system. A typical pump in a domestic heating system may consume 50-150 W (e.g., 65-100 W) when running. A boiler may include a unit having burner and heat exchanger integral with the pump or a separate pump external to the burner/heat exchanger unit.

Many heating systems also use boiler fans, as it is typical for modern boilers to have fan-assisted flues rather than natural draught flues and a permanent pilot. The increasing gas flow resistance from larger heat exchange surface areas in high-efficiency boilers has increased the power requirements of the boiler fan. In condensing boilers, the boiler fan typically requires increased fan power to overcome the fluid losses across the extra heat exchanger surfaces. Modulating burners also require speed control to ensure the gas/air modulation ratio can be maintained. The boiler fan may be responsible for approximately a third of the total power consumption of the burner. A typical fan in a domestic heating system may consume 20-135 W, such as 30-50 W, when running, depending on the boiler size.

The control unit, which can be an electrical or electromechanical control unit, typically consumes a small amount of instantaneous power (e.g., 0.4-5.0 W, such as 2-4 W), but it is always on. Thus, the control unit may be responsible for between 5-10% (e.g., about 8%) of the total power consumption of the boiler. Many boilers also include components such as electronic thermostats, flame detection and spark ignition systems that utilize an on-board power supply that results in a quiescent or “standby” power consumption. This “standby” power consumption can be between 5-15 W (e.g., about 8 W), and may account for between 10-20 (e.g., 15-20%) of the total power consumption of the boiler. Some boilers may also use electric heaters (e.g., immersion heaters, trace heaters) to maintain the fluid medium (e.g., water) at a desired temperature (e.g., 60° C.) and reduce boiler warmup time. Such electric heaters, when used, may consume 15-30 W (e.g., about 25 W).

Electrically actuated valves include motorized zone valves (e.g., two-port and three-port type valves). Many domestic boiler heating systems use motor open, spring return-type valves, which may consume about 5 W continuously while the valve is open. Other valves, such as motor open motor off (MOMO) type valves may consume about 6 W during a valve state change. Typically, the motorized zone valves may account for about 4-6% of the total power consumption of the boiler. A separate valve system for the burner gas may include a pair of solenoid valves (for safety reasons) which may consume around 6 W while the burner is firing. The gas valve may account for between about 2-5% (e.g., around 3%) of the total power consumption of the boiler.

Thus, a typical boiler for heating and/or hot water as described above may require at least about 100 W of electric power for operation, such as 100-250 W (e.g., 150-200 W, such as 175 W, or 200-250 W, such as 225 W). Some boilers may require at least about 250 W of electric power, such as 250-500 W, for operation, such as 250-400 W (e.g., 250-350 W, such as 300 W, or 350-450 W, such as 400 W or more).

In various embodiments, a boiler includes an integrated thermoelectric power generation (TEG) system for generation of thermal and electrical energy. The thermoelectric power generation (TEG) system may use a temperature gradient within the boiler, such as between a hot combustion product (e.g., a flame) and a lower-temperature fluid (e.g., water) to provide a temperature difference across one or more thermoelectric conversion elements and thereby generate electricity. In embodiments, the boiler may be a self-powered boiler, meaning that the net electrical power produced by the thermoelectric power generation system is equal to or greater than the total electric power consumed by the boiler under normal (e.g., steady state) operating conditions. Electricity from the TEG system may be provided to boiler electrical components.

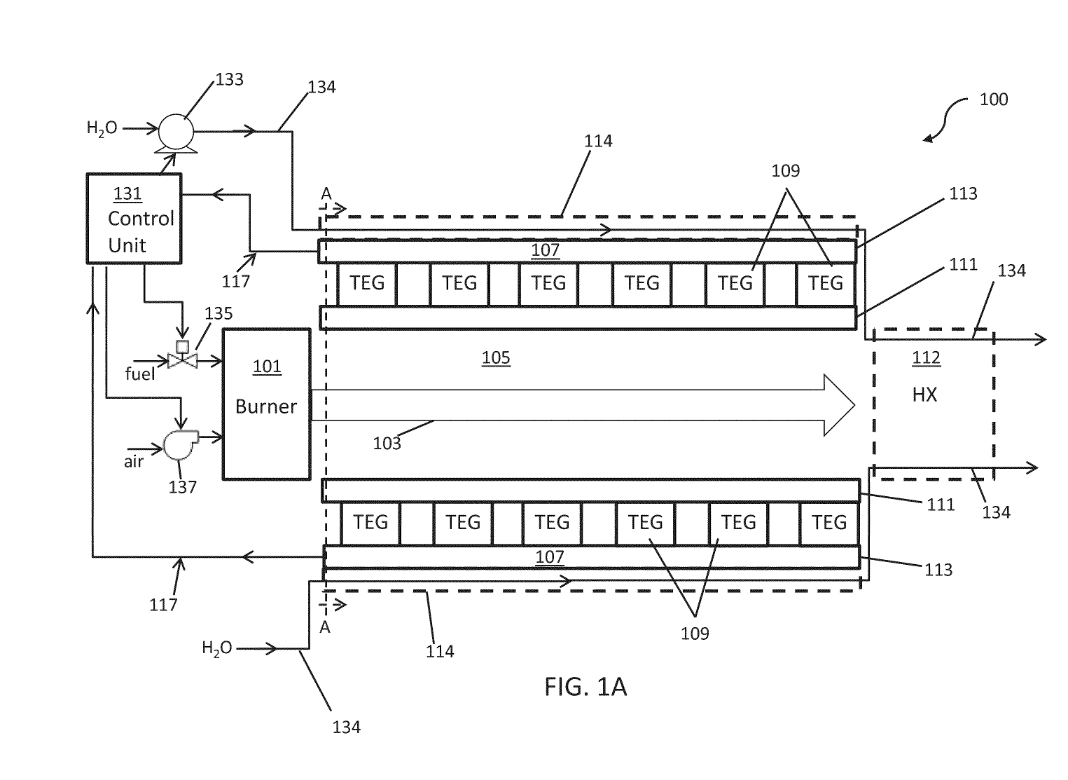

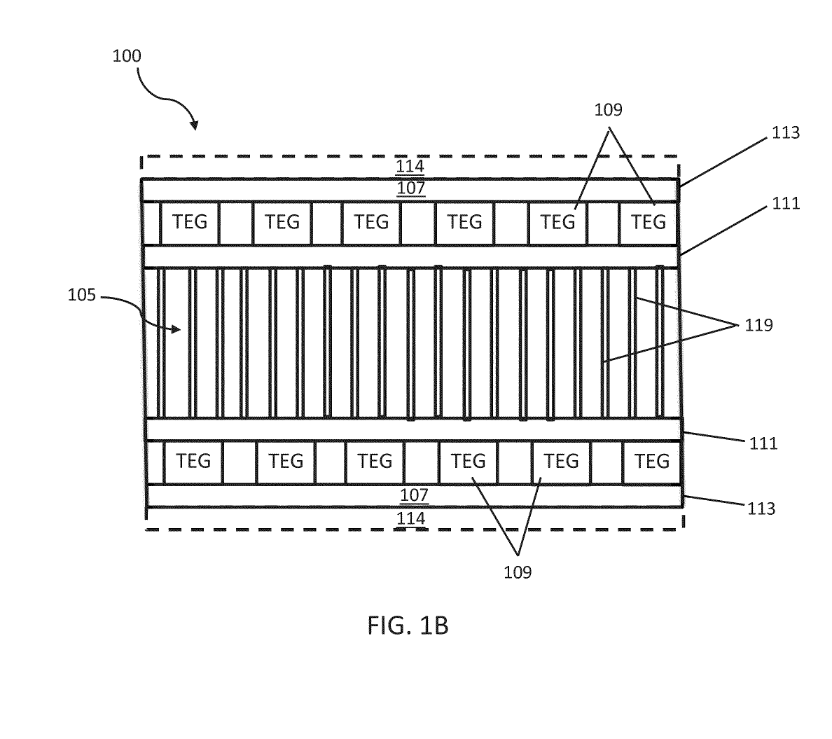

FIG. 1A is a schematic cross sectional side view of a boiler 100 having a burner 101 that burns a fuel (e.g., a hydrocarbon fuel, such as natural gas) to produce a hot combustion product 103 (i.e., a flame). The hot combustion product 103 is directed through a conduit 105, heating the conduit 105 to a high temperature. A plurality of thermoelectric generator (TEG) modules 109 are provided between the high temperature conduit 105 and a lower temperature region 107 external to the conduit. The modules 109 may be provided between a pair of support elements 111, 113. The TEG modules 109 may be positioned between the high-temperature conduit 105 (i.e., hot zone) and the lower temperature region 107 (i.e., cool zone) outside the conduit. One of the support elements 111 or 113 may be an outer wall of conduit 105. Each of the support elements 111, 113 may be made of a thermally conductive material. Thus, one side of the TEG modules 109 (i.e., the “hot side”) may be thermally coupled to the “hot zone” of conduit 105, and the other side of the TEG modules 109 (i.e., the “cold side”) may be thermally coupled to the “cool zone” of the lower temperature region 107 outside the conduit 105. In various embodiments, a lower temperature fluid 134, such as water for the boiler, maybe thermally coupled to the lower temperature region 107 and may be flowed through a cooling or “working” fluid conduit or manifold, e.g., “water wall” 114 indicated schematically by dashed lines.

In operation, fuel and air are fed to burner 101, which combusts the fuel/air mixture to produce the hot combustion product 103. A pump 133 circulates water 134 through the boiler 100 (e.g., through conduit 114 and heat exchanger 112) to transfer heat from the hot combustion product 103 to the water 134. The heated water 134, which may be vaporized, exits heat exchanger 112 for use in heating, residential, office or industrial hot water supply and/or other applications (e.g., power generation). After the water 134 cools, and optionally condenses, the water 134 may be recirculated to pump 133. A control unit 131 may include circuitry/logic for monitoring and controlling operation of the boiler 100 by, for instance, regulating the water temperature by controlling the operation of pump 133 and/or the fuel and air feeds to the burner 101 via electrically actuated valve 135 and fan/blower 137, respectively.

The TEG modules 109 may include a plurality of thermoelectric converters (e.g., one or more “couples” or interconnected pairs of p-type and n-type legs of thermoelectric material) each including a first (hot) side in thermal communication with the high-temperature conduit 105, a second (cold) side in thermal communication with the lower temperature region 107. Electrically conductive leads 117 may provide appropriate electrical coupling within and/or between thermoelectric converters, and may be used to extract electrical energy generated by the converters. The electrical energy generated by the TEG modules 109 may be provided over leads 117 to a load, which may be one or more components of the boiler 100, such as the control unit 131, electrically actuated valve(s) 135, fan or blower 137, water pump 133, a safety device, etc. The load powered by the TEG modules 109 may further comprise other components external to the boiler. At least a portion of the electrical power from the TEG modules 109 may be provided to an energy storage device (e.g., rechargeable battery, ultracapacitor, etc.) for later use or for start-up of the boiler. In some embodiments, at least a portion of the electrical power from the TEG modules 109 may be provided/sold to a power grid. The control unit 131 may be configured to operate the boiler 100 to provide a power output from the TEG modules 109 in excess of the power required to operate the boiler 100, and the excess power may be used to power one or more additional devices and/or to satisfy transient power demands on an as-needed basis. In embodiments, the TEG modules 109 may generate more than 400 W of electricity, which is more than twice the power needed to drive a typical boiler. In embodiments, the TEG modules 109 may use thermal energy from the boiler to generate electric power in an amount equal to at least the total amount of electric power required by the boiler for operation, such as more than 100 W of electric power, such as 100-250 W (e.g., 150-200 W, such as 175 W, or 200-250 W, such as 225 W), or more than 250 W (e.g., 250-500 W) of electric power, such as 250-400 W (e.g., 250-350 W, such as 300 W, or 350-450 W, such as 400 W). At start-up, the boiler 100 may plug into an outlet or use battery power or a pilot light. A control system may then switch to TEG power when it detects sufficient power at steady state. The boiler 100 of the present invention may be powered by the TEG modules 109 when other source(s) of power are not available, such as during a power outage, and may be used in areas where grid power is not available.

The boiler 100 may include heat exchange elements to conduct heat from the combustion product 103 of burner 101 to the “hot side” of the thermoelectric modules 109. For example, the high-temperature conduit 105 may include a plurality of thermally conductive plate elements 119 to provide a plate-type heat exchanger, as shown in FIG. 1B, which is a cross-section view taken along line A-A of FIG. 1A.

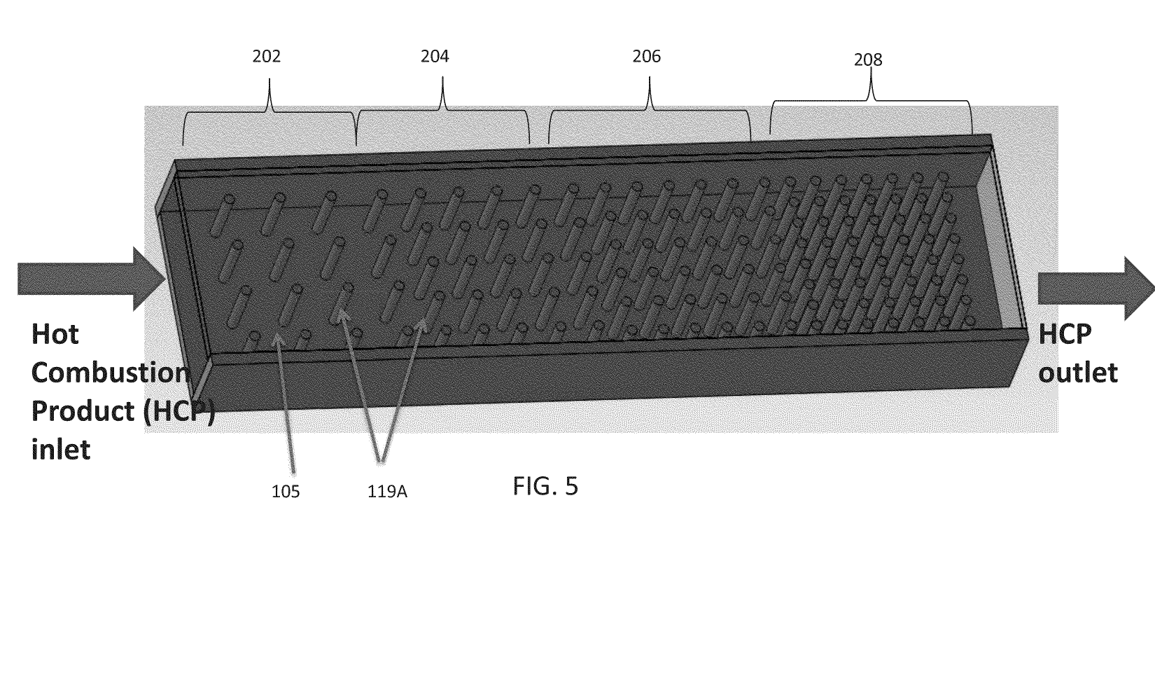

Other heat exchange configurations, such as a fin type heat exchanger, may also be employed. A fin type head exchanger may include a plurality of plate fins, pin fins, or both. When a fin type heat exchanger is utilized, a packing fraction of the fins may vary from a first packing fraction proximate the inlet to conduit 105 to a second denser packing fraction proximate the outlet of conduit 105, in order to provide a substantially uniform temperature to the hot sides of TEG modules 109, such as described in U.S. application Ser. No. 13/924,826 filed Jun. 24, 2013, the entire contents of which are incorporated herein by reference for all purposes. FIG. 5 illustrates a fin-type heat exchanger in which the spacing of the fins 119A (pin-type fins in this embodiment) may be varied along the direction of fluid flow and/or in a direction transverse to fluid flow. In general, the fin packing fraction (i.e., fin density) may increase from a first packing fraction proximate the fluid inlet of the heat exchanger to a second packing fraction proximate the fluid outlet of the heat exchanger. The packing fraction may increase as a stepwise function, such as shown in FIG. 5, in which the heat exchanger includes four sections 202, 204, 206, 208 of gradually increasing fin packing fractions. In some embodiments, the fin packing fraction may be continuously graded over all or a portion of the length of the heat exchanger.

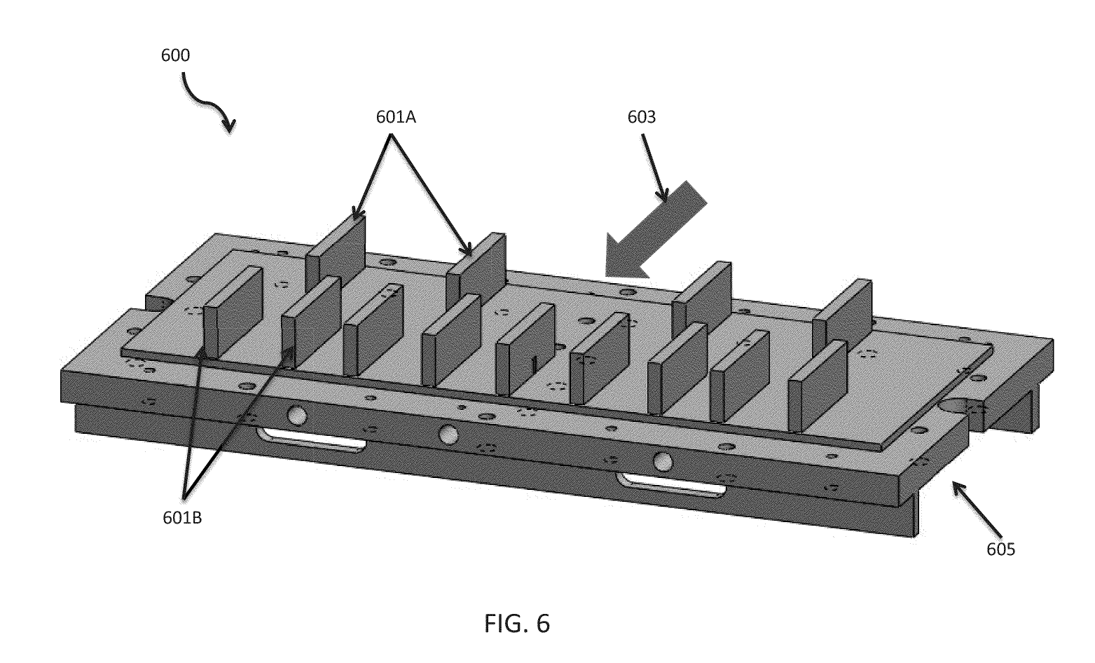

FIG. 6 illustrates an embodiment of a gradient fin heat exchanger 600 having a plurality of plate fins 601. In this embodiment, the fin packing fraction (i.e., fin density) of the plate fins 601 (e.g., the size of plate fins 601 and/or the spacing between plate fins 601) may be varied along the direction of fluid flow (indicated by arrow 603) and/or in a direction transverse to fluid flow. In the embodiment of FIG. 6, a first group of plate fins 601A proximate the fluid inlet of the heat exchanger 600 has a first spacing between the plate fins 601A, and a second group of plate fins 601B, located downstream of the first group along the direction of fluid flow 603, has a second spacing between the plate fins 601B. The plate fins 601B of the second group are more closely spaced (i.e., have a higher packing fraction). Additional groups of plate fins having varying spacing may be provided downstream of fins 601B and/or upstream of fins 601A. Each group of fins may be offset relative to the fins of the adjacent group(s), as shown in FIG. 6, to promote contact between the fluid flow and the fins. Alternatively, the fins may be aligned with the fins of the adjacent group(s). The packing fraction for each group of fins may increase in a continuous or stepwise fashion over all or a portion of the length of the heat exchanger. The heat exchanger 600 may include a mounting surface 605 in thermal contact with the fins 601A, 601B to which one or more thermoelectric generator (TEG) modules may be mounted. The fins 601, 601B may be configured to provide a substantially uniform temperature across the mounting surface 605, so as to provide a substantially uniform temperature over the “hot” sides of the TEG elements.

In various embodiments, the hot combustion product 103 (i.e., flame) entering conduit 105 may have a temperature of greater than about 1000° C., such as about 1200° C. or more. The temperature on the “hot” side of the thermoelectric modules 109 may be 400° C. or more (e.g., 500° C. or more), such as 600-700° C. The temperature on the “cold” side of the thermoelectric modules 109 may be 200° C. or less, such as 150° C. or less (e.g., 100-130° C., such as ˜115° C.). The hot combustion product 103 leaving the conduit 105 may have a temperature greater than about 650° C., such as between 670-900° C.

In various embodiments, the hot combustion product 103 exiting the conduit 105 may optionally be provided to a heat exchanger 112 where thermal energy from the combustion product 103 may be transferred to a fluid 134, such as water or molten salt (e.g., water in a hot water heating boiler). As shown in FIG. 1A, the heat exchanger 112 is located downstream of the TEG modules 109, although in other embodiments, the heat exchanger 112 may be located upstream of or co-located with the TEG modules 109 (e.g., in conduit 105).

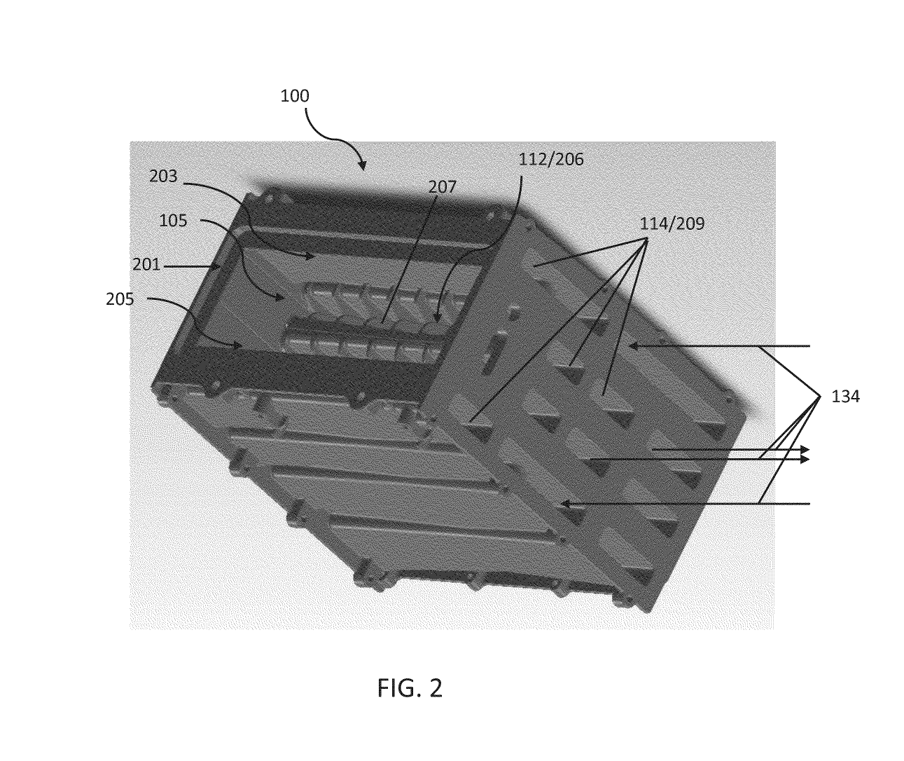

FIG. 2 illustrates an embodiment of a boiler 100 and shows areas where the TEG modules may be installed. In this embodiment, a burner 101 (shown in FIG. 1A but not shown in FIG. 2 for clarity) may be mounted in a burner mounting area 201. Hot combustion product 103 from the burner may be directed into conduit 105 and then into a heat exchange region 206 (which corresponds to the schematic heat exchanger 112 in FIG. 1A) having a plurality of heat exchange elements, such as fins 207. The boiler 100 also includes a plurality of water flow channels 209 (which correspond to channels 114 shown schematically in FIG. 1A) that extend adjacent to conduit 105 and through the heat exchange region 206. Water may flow through the channels 209 in a series flow (i.e., the water shown by the arrows 134 follows a serpentine path through each of the channels 209) or in a parallel flow (i.e., the water flow is distributed across the channels 209) or in a combination of series and parallel flow.

In this embodiment shown in FIG. 2, the water channels 209 and hot combustion product 103 in conduit 105 have a cross-flow configuration. In this configuration, the water would flow in and out of the page rather than left to right as shown in FIG. 1A In other embodiments, the water channels 209 and hot combustion product 103 in conduit 105 may have a counter-flow or co-flow configuration, or a combination of counter-flow, co-flow and/or cross-flow configurations.

As is shown in FIG. 2, the boiler 100 includes internal surfaces, including a top wall 203 and a bottom wall 205, which are adjacent to the burner and between the hot combustion product 103 conduit 105 and the water channels 209. One or more TEG modules, such the modules 109 shown in FIGS. 1A-B, may be mounted to the top wall 203 and/or the bottom wall 205, such that the hot side of the modules is in thermal contact with the hot combustion product from the burner and the cold side of the modules is in thermal contact with the water flowing through channels 209. Heat exchange elements, such as the fins 119 shown in FIG. 1B, may extend from the top and bottom walls 203, 205 of the boiler to promote heat transfer to the TEG modules. TEG modules may be provided in other portions of the boiler 100, such as on the side walls of the boiler or within the heat exchange region 206. The TEG power generation modules of the various embodiments may be easily retrofitted into existing boiler designs to provide a self-powered boiler.

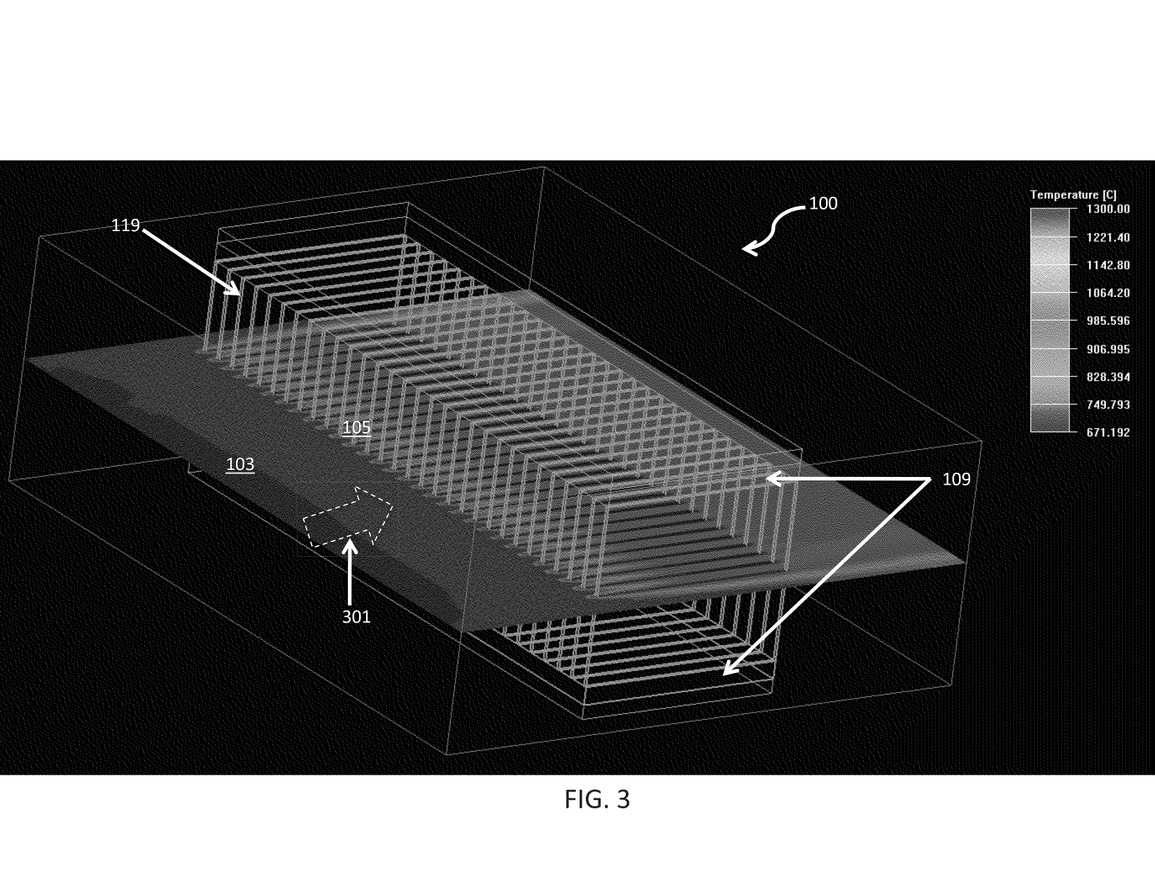

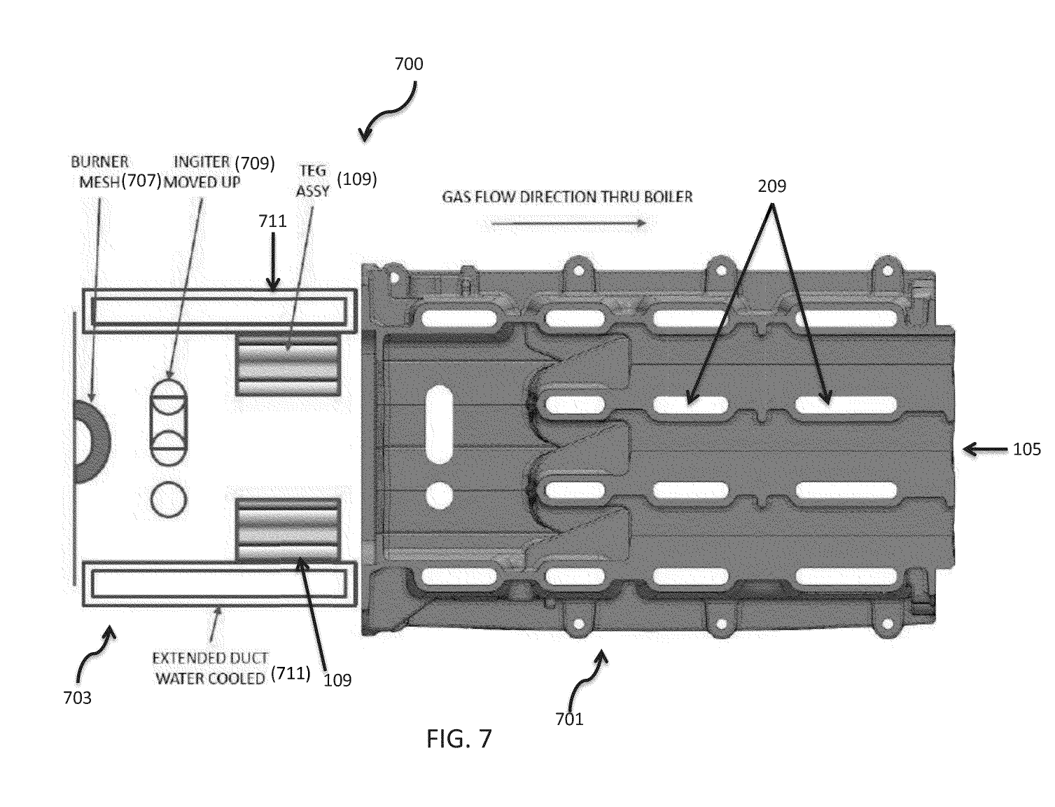

FIG. 7 illustrates an alternative embodiment of a boiler 700 having a heat exchanger unit 701 and a burner unit 703 with one or more TEG modules 109 integrated into the burner unit 703. In this embodiment, the heat exchanger unit 701 may be similar to the boiler 100 of FIG. 3, and may include a heat exchange region 206 including a conduit 105 through which the burner exhaust flows and a plurality of water flow channels 209 extending through the heat exchange region 206 in thermal contact with the burner exhaust. The heat exchanger unit 701 of FIG. 7 differs from the FIG. 2 embodiment in that the burner components are moved outside the burner mounting area (i.e., 201 in FIG. 2) and are provided in a separate burner unit 703. The burner unit 703 may include typical burner components, such as a burner mesh 707 and igniter 709. The burner unit 703 also includes one or more TEG modules 109 mounted to an interior surface of the burner unit 703. The “hot” side of the TEG module 109 may be in thermal contact with the burner exhaust (i.e., before the burner exhaust enters the conduit 105 of heat exchanger unit 701). The “cold” side of the TEG module 109 may be in thermal contact with a heat sink, such as duct 711, through which a cooling fluid (e.g., water) may flow. The duct(s) 711 may be coupled to the water flow channels 209 of the heat exchanger unit 701 (i.e., may be part of the main boiler water circulation path), or may be separate from the boiler water path. Additional TEG modules (not shown) may optionally be provided within the heat exchanger unit 701.

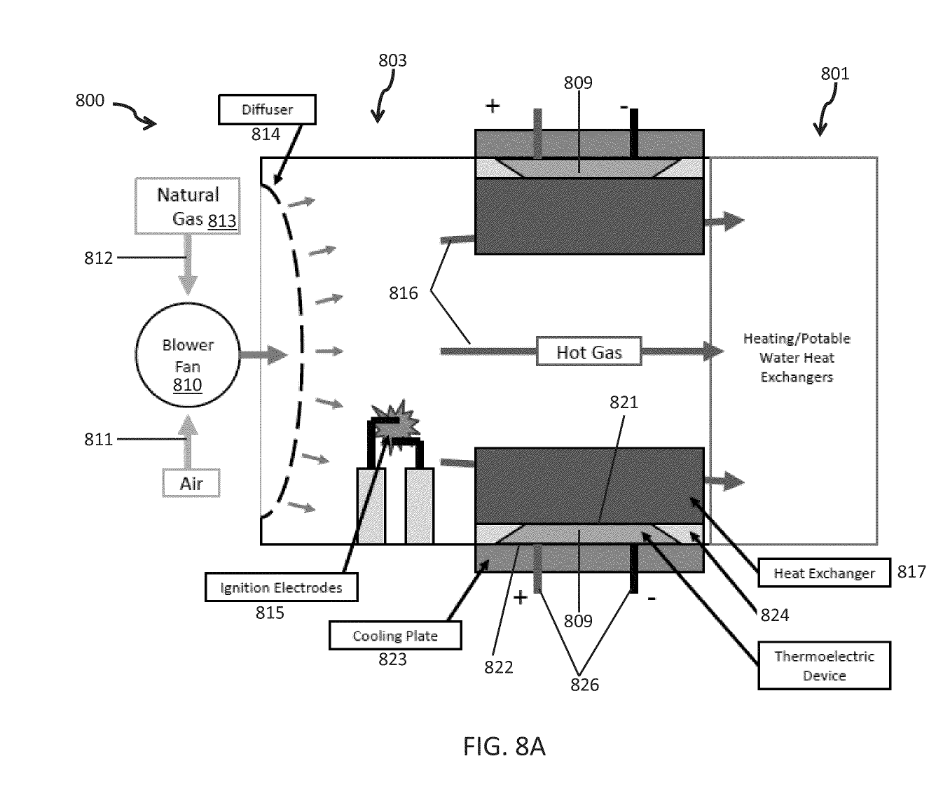

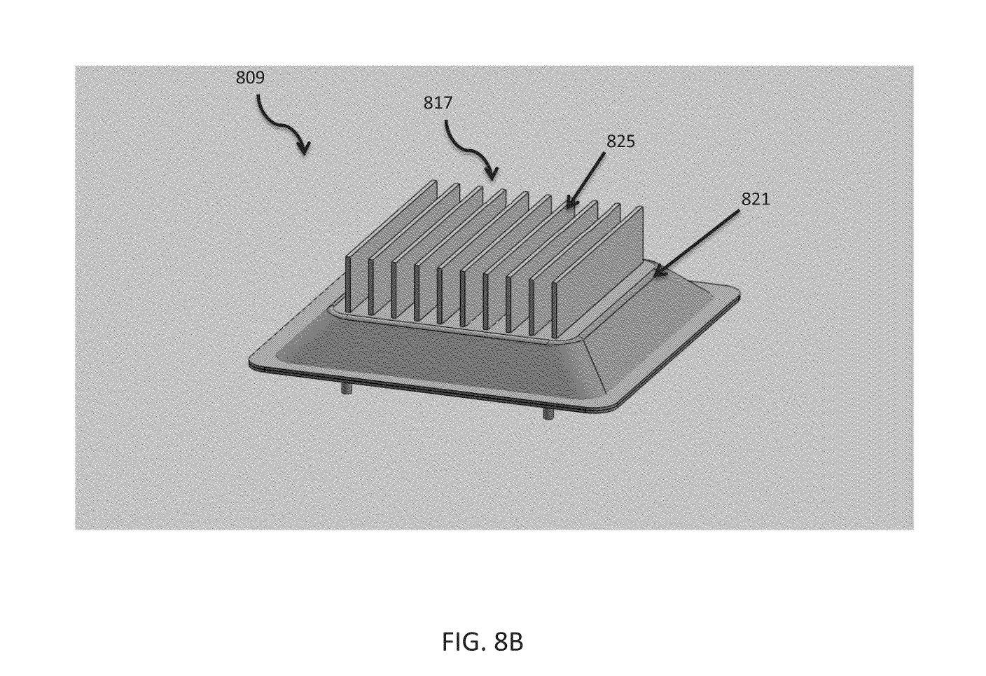

FIG. 8A illustrates yet another embodiment of a boiler 800 having a heat exchanger portion 801 and a burner portion 803 with one or more TEG modules 809 integrated into the burner portion 803. In this embodiment, the heat exchanger portion 801 may be similar to the boiler 100 of FIG. 3, and may include one or more heat exchangers for transfer of heat from the hot burner exhaust gas to a fluid medium (e.g., heating/potable water) which may flow through the heat exchanger portion 801 through a plurality of conduits (not shown). A blower fan 810 may direct air 811 and fuel (e.g., natural gas 812, such as from a natural gas source 813) to the burner portion 803, which may be directed through a diffuser 814. The diffused air/fuel mixture may be ignited by ignition electrodes 815 and combusted to produce a hot gas flow 816. At least a portion of the hot gas flow 816 flows through one or more heat exchangers 817 that are coupled to a TEG module 809. The heat exchangers 817 may have any suitable configuration, such as a pin-fin or plate-fin type heat exchanger as described above. In embodiments, the heat exchanger 817 may have a gradient pin-fin design as shown in FIG. 5 or a gradient plate-fin design as shown in FIG. 6. In other embodiments, the heat exchanger 817 may have a conventional non-gradient design. The heat exchanger 817 may transfer heat from the hot gas flow 816 to a cover 821 of the thermoelectric module 809 which may be in thermal contact with the “hot” sides of a plurality of thermoelectric elements (e.g., interconnected pairs of p-type and n-type thermoelectric material legs) contained within the module 809. A bottom surface 822 of the module 809 opposite the cover 821 may be thermally coupled to a cooling plate 823 which may function as a heat sink and help to maintain a desired temperature differential between the “hot” and “cold” sides of the thermoelectric elements within the module 809. In embodiments, the cooling plate 823 may be coupled to or form a portion of a boiler water tube. Thus, boiler water that is at a lower temperature than the temperature within the burner portion 803 may flow over or within the cooling plate 823 to cool the “cold” side of the TEG module 809. The cooling plate 823 may form a portion of a chamber wall of the burner portion 803 with the TEG module 809 located between the interior of the burner portion chamber and the cooling plate 823. In some embodiments, the cooling plate 823 may be a separate component that is mounted to or otherwise thermally coupled to the cold side of the TEG module 809. A thermal insulation material 824 may be located adjacent to the side surfaces of the module 809 to reduce heat loss from the hot combustion gases 816 to the cooling plate 823. The thermal insulation material 824 may be, for example, a ceramic material, an aerogel, fiberglass or any suitable material having low thermal conductance that can withstand the temperatures within the burner portion 803. The thermal insulation material 824 may help ensure that the majority of the heat from the heat exchanger 817 is delivered to the “hot” side of the TEG module 809. Conductive leads 826 may be connected to the thermoelectric elements within the module 809 and may extend out of the module 809 for extracting electrical power from the module 809. The electrical power may be used to power components of the boiler 800, such as the blower fan 810, pump(s), valve(s), control system(s), etc., as described above.

FIG. 8B illustrates an embodiment of a thermoelectric generator module 809 having a heat exchanger 817 comprised of an array of fins 825 directly coupled to a module cover 821. The module 809 may include an electrically interconnected package of thermoelectric converters (e.g., pairs of p-type and n-type thermoelectric legs). The cover 821 (or casing) may be made of a thermally conductive material that is located over the hot side of the module 809 and conducts thermal energy from an external heat source to the hot sides of the respective thermoelectric legs. In embodiments, the cover 821 may be made of an electrically conductive material (e.g., metal or metal alloy). When the cover 821 is electrically conductive, an electrical isolator (not shown) formed of electrically insulating, thermally conductive material, such as a ceramic material, may be provided between the cover 821 and the adjacent hot end of the thermoelectric converters. For example, a ceramic coating may be provided over all or a portion of the interior surface of the cover 821 and/or over the outer surfaces of the metal headers that may connect pairs of p-type and n-type thermoelectric legs.

The heat exchanger 817 in this embodiment comprises a plurality of fins 825 directly attached to the module cover 821. The heat exchange fins 825 in this embodiment comprise plate type fins, although pin type fins and combinations of plate and pin type fins could also be used. In addition, this embodiment the plate fins 825 are evenly spaced and oriented generally parallel to the direction of fluid flow, although it will be understood that other configurations may be used. For example, a gradient fin heat exchanger may be used where the fin packing fraction is varied along the direction of fluid flow and/or in a direction transverse to fluid flow, as described above.

The fins 825 may be made of a thermally-conductive material, such as a metal or metal alloy, and may be made from the same or different material than the portion of the cover 821 to which they are attached. The fins 825 may be thermally matched to the cover 821 (e.g., made from a material having a coefficient of thermal expansion (CTE) within about 10%, such as 0-5%, including 0-1% of the cover material). In embodiments, direct attachment of fins 825 to the module cover 821 may eliminate thermal interface problems between the heat exchanger and the thermoelectric generator module 809, and may significantly enhance the performance of the module 809. The fins 825 may be attached to the cover 821 using any suitable technique, such as via brazing, soldering, welding, solid state diffusion, use of a high-temperature adhesive and/or via mechanical fasteners.

In embodiments, a plurality of modules 809 having heat exchangers 817 directly attached to the module cover 821 as shown in FIG. 8B may be disposed along a path of a fluid flow (e.g., along an interior of a conduit, such as shown in FIGS. 1A, 7 and 8A), and the fin packing fraction (i.e., fin density) of the fins 825 of each respective module 809 (e.g., the size the fins 825 and/or the spacing of the fins 825) may be varied along the direction of fluid flow and/or in a direction transverse to fluid flow. Thus, a relatively uniform temperature may be obtained at the hot sides of each module 809.

The thermoelectric converters of the TEG modules 109, 809 according to any of the above-described embodiments may be made from a variety of bulk materials and/or nanostructures. The converters preferably comprise plural sets of two converter elements—one p-type and one n-type semiconductor converter post or leg which are electrically connected to form a p-n junction. The thermoelectric converter materials can comprise, but are not limited to, one of: half-Heuslers, Bi₂Te₃, Bi₂Te₃₋ₓSeₓ (n-type)/Biₓ Se₂₋ₓTe₃ (p-type), SiGe (e.g., Si₈₀Ge₂₀), PbTe, skutterudites, Zn₃Sb₄, AgPbₘSbTe₂₊ₘ, Bi₂Te₃/Sb₂Te₃ quantum dot superlattices (QDSLs), PbTe/PbSeTe QDSLs, PbAgTe, and combinations thereof. The materials may comprise compacted nanoparticles or nanoparticles embedded in a bulk matrix material. For example, see U.S. patent application Ser. No. 11/949,353 filed Dec. 3, 2007, which is incorporated herein by reference for all purposes, for a description of exemplary materials.

As used herein, a “nanoparticle” or “nanosized” structure, generally refers to material portions, such as particles, whose dimensions are less than 1 micron, preferably less than about 100 nanometers. For example, nanoparticles may have an average cross-sectional diameter in a range of about 1 nanometer to about 0.1 micron, such as 10-100 nm. Nanostructured bulk materials which comprise compacted semiconductor and/or intermetallic nanoparticles are attractive since the materials are in a form that is compatible with use in a boiler yet have a relatively high figure-of-merit (ZT) and are economical. Such nanostructured bulk materials can be compacted from nanoparticles of the same material (e.g., SiGe, BiTe, half-Heusler material, etc.), or compacted particles of different materials, in which nanoparticles of one material form a host matrix and the nanoparticles of the second material form inclusions in the host matrix. The particles may be consolidated (compacted) using hot pressing or direct current induced hot pressing. The consolidated, dense bulk materials are nanostructured with grains having at least one of a median grain size and a mean grain size less than one micron, such as grains having a mean grain size less than 300 nm in which at least 90% of the grains are less than 500 nm in size. In one embodiment, the grains have a mean grain size in a range of 10-300 nm. In one embodiment, the grains have a mean size of around 200 nm. Typically, the grains have random orientations. Further, grains may include 5-50 nm size (e.g., diameter or width) nanodot inclusions within the grains.

Such nanostructured thermoelectric materials have been shown to have a relatively high figure-of-merit, ZT, defined by ZT=(S²σ/κ)T, where σ is the electrical conductivity, S the Seebeck coefficient, κ the thermal conductivity, and T the absolute temperature. The nanostructured materials generally have a power factor (S²σ) comparable to the same materials produced using conventional techniques (i.e., non-nanostructured materal), but exhibit a much lower thermal conductivity κ. The significant reduction in thermal conductivity in the nanostructured materials may be attributed to the increased phonon scattering at the numerous interfaces of the random nanostructures. The combination of relatively high power factor and low thermal conductivity make the nanostructured thermoelectric materials an excellent candidate as a power generator for a self-powered boiler 100.

In preferred embodiments, the thermoelectric elements used in the boiler 100 employ half-Heusler materials. Suitable half-Heusler materials and methods of fabricating half-Heusler thermoelectric elements are described in U.S. patent application Ser. No. 13/330,216 filed Dec. 19, 2011 and Ser. No. 13/719,966 filed Dec. 19, 2012, the entire contents of both of which are incorporated herein by reference for all purposes. Half-Heuslers (HHs) are intermetallic compounds which have great potential as high temperature thermoelectric materials for power generation. HHs are complex compounds: MCoSb (p-type) and MNiSn (n-type), where M can be Ti or Zr or Hf or combination of two or three of the elements. Sn and Sb can be substituted by Sb/Sn. They form in cubic crystal structure with a F4/3m (No. 216) space group. These phases are semiconductors with 18 valence electron count (VEC) per unit cell and a narrow energy gap. The Fermi level is slightly above the top of the valence band. The HH phases have a fairly decent Seebeck coefficient with moderate electrical conductivity. The performance of thermoelectric materials depends on ZT, defined by ZT=(S²σ/κ)T, where σ is the electrical conductivity, S the Seebeck coefficient, κ the thermal conductivity, and T the absolute temperature. Half-Heusler compounds may be good thermoelectric materials due to their high power factor (S²σ).

The dimensionless thermoelectric figure-of-merit (ZT) of conventional HHs is lower than that of many other state-of-the-art thermoelectric materials. Recently, enhancements in the dimensionless thermoelectric figure-of-merit (ZT) of n-type half-Heusler materials using a nanocomposite approach has been achieved. A peak ZT of 1.0 was achieved at 600-700° C., which is about 25% higher than the previously reported highest value. The materials may be made by ball milling ingots of composition Hf_{0.75}Zr_{0.25}NiSn_{0.99}Sb_{0.01} into nanopowders and hot pressing (e.g., DC hot pressing or without application of current) the powders into dense bulk samples. The ingots may be formed by arc melting the constituent elements. The ZT enhancement mainly comes from reduction of thermal conductivity due to increased phonon scattering at grain boundaries and crystal defects, and optimization of antimony doping.

By using a nanocomposite half-Heusler material, a greater than 35% ZT improvement from 0.5 to 0.8 in p-type half-Heusler compounds at temperatures above 400° C. has been achieved. Additionally, a 25% improvement in peak ZT, from 0.8 to 1.0 at temperatures above 400° C., in n-type half-Heusler compounds by the same nanocomposite approach has been achieved. The ZT enhancement is not only due to the reduction in the thermal conductivity but also an increase in the power factor. These nanostructured samples may be prepared, for example, by hot pressing a ball milled nanopowder from ingots which are initially made by an arc melting process. The hot pressed, dense bulk samples may be nanostructured with grains having a mean grain size less than 300 nm in which at least 90% of the grains are less than 500 nm in size. In some cases, the grains have a mean size in a range of 10-300 nm, such as a mean size of around 200 nm. Typically, the grains have random orientations. Further, many grains may include 10-50 nm size (e.g., diameter or width) nanodot inclusions within the grains.

Embodiments of the half-Heusler materials may include varying amounts of Hf, Zr, Ti, Co, Ni, Sb, Sn depending on whether the material is n-type or p-type. Other alloying elements such as Pb may also be added. Example p-type materials include, but are not limited to, Co containing and Sb rich/Sn poor Hf_{0.5}Zr_{0.5}CoSb_{0.8}Sn_{0.2}, Hf_{0.3}Zr_{0.7}CoSb_{0.7}Sn_{0.3}, Hf_{0.5}Zr_{0.5}CoSb_{0.8}Sn_{0.2}+1% Pb, Hf_{0.5}Ti_{0.5}CoSb_{0.8}Sn_{0.2}, and Hf_{0.5}Ti_{0.5}CoSb_{0.6}Sn_{0.4}. Example n-type materials include, but are not limited to, Ni containing and Sn rich/Sb poor Hf_{0.75}Zr_{0.25}NiSn_{0.975}Sb_{0.025}, Hf_{0.25}Zr_{0.25}Ti_{0.5}NiSn_{0.994}Sb_{0.006}, Hf_{0.25}Zr_{0.25}NiSn_{0.99}Sb_{0.01} (Ti_{0.30}Hf_{0.35}Zr_{0.35})Ni(Sn_{0.994}Sb_{0.006}), Hf_{0.25}Zr_{0.25}Ti_{0.5}NiSn_{0.99}Sb_{0.01}, Hf_{0.5}Zr_{0.25}Ti_{0.25}NiSn_{0.99}Sb_{0.01} and (Hf,Zr)_{0.5}Ti_{0.5}NiSn_{0.998}Sb_{0.002}.

The ingot may be made by arc melting individual elements of the thermoelectric material in the appropriate ratio to form the desired thermoelectric material. Preferably, the individual elements are 99.9% pure. More preferably, the individual elements are 99.99% pure. In some cases, two or more of the individual elements may first be combined into an alloy or compound and the alloy or compound used as one of the starting materials in the arc melting process. Ball milling may result in a nanopowder with nanometer size particles that have a mean size less than 100 nm in which at least 90% of the particles are less than 250 nm in size. In one example, the nanometer size particles have a mean particle size in a range of 5-100 nm.

It has been discovered that the figure of merit of thermoelectric materials improves as the grain size in the thermoelectric material decreases. In one example of a method for fabricating thermoelectric materials, thermoelectric materials with nanometer scale (less than 1 micron) grains are produced, i.e., 95%, such as 100% of the grains have a grain size less than 1 micron. Preferably, the nanometer scale mean grain size is in a range of 10-300 nm. This method may be used to fabricate any thermoelectric material and includes making half-Heusler materials with nanometer scale grains. The method may be used to make both p-type and n-type half-Heusler materials. In one example, the half-Heusler material is n-type and has the formula Hf_{1+δ-x-y}ZrₓTi_{y}NiSn_{1+δ-z}Sb_{z}, where 0≦x≦1.0, 0≦y≦1.0, 0≦z≦1.0, and −0.1≦δ≦0.1 (to allow for slightly non-stoichiometric material), such as Hf_{1-x-y}ZrₓTi_{y}NiSn_{1-z}Sb_{z}, where 0≦x≦1.0, 0≦y≦1.0, and 0≦z≦1.0 when 8=0 (i.e., for the stoichiometric material). In another example, the half-Heusler is a p-type material and has the formula Hf_{1+δ-x-y}ZrₓTi_{y}CoSb_{1+δ-z}Sn_{z}, where 0≦x≦1.0, 0≦y≦1.0, 0≦z≦1.0, and −0.1≦δ≦0.1 (to allow for slightly non-stoichiometric material), such as Hf_{1-x-y}ZrₓTi_{y}CoSb_{1-z}Sn_{z}, where 0≦x≦1.0, 0≦y≦1.0, and 0≦z≦1.0 when 8=0 (i.e., for the stoichiometric material).

FIG. 3 shows results of a simulation of the temperature within the conduit 105 of a boiler 100 according to an embodiment. As the combustion product 103 propagates within conduit 105 in the direction of arrow 301, the combustion product 103 contacts plate-type heat exchange elements 119 in conduit 105. A portion of the heat from the combustion product 103 is transferred to the heat exchange elements 119, which in turn transfer heat to the hot side of the TEG modules 109. The TEG modules 109 comprise half-Heusler thermoelectric materials. As shown in this simulation, the temperature of the combustion product 103 entering the conduit 105 is approximately 1250-1300° C. As the combustion product 103 travels through the conduit 105 and across heat exchange elements 119, the combustion product 103 cools to an outlet temperature of between about 670-800° C. The combustion product 103, still at elevated temperature, may then be used to heat water or another fluid in heat exchanger 112.

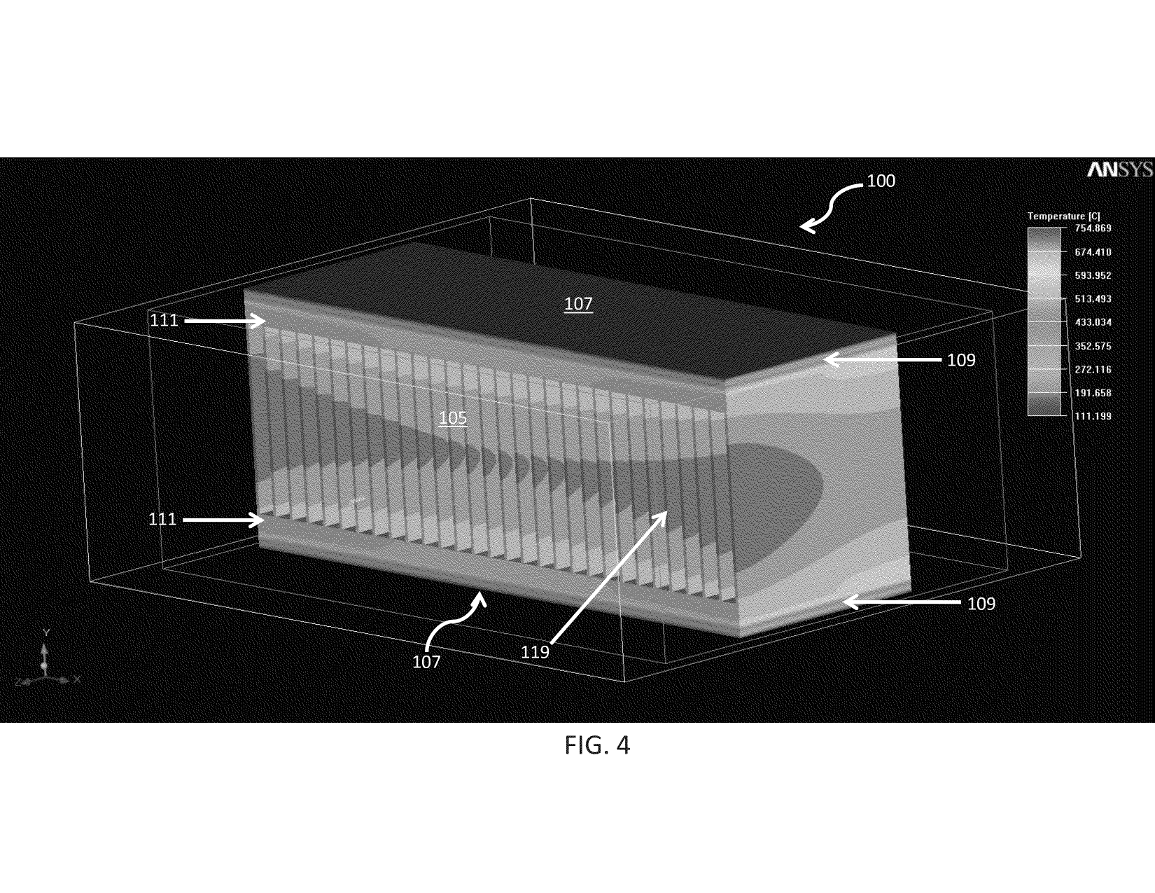

FIG. 4 shows the results of a simulation of the temperature within the heat exchange elements 119 and TEG modules 109. As illustrated in FIG. 4, the temperature on the hot side 105 of the modules 109 is approximately 630° C., while the temperature on the cold side 107 is approximately 115° C. The heat flow is 5600 W and the pressure drop is 5.7 Pa. At this temperature gradient, the electric power generated by the TEG modules 109 is 446 W.

The thermoelectric material (i.e., legs) of the TEG modules may be formed of a nanostructured material with grains having at least one of a median grain size and a mean grain size less than one micron, such as grains having a mean grain size less than 300 nm in which at least 90% of the grains are less than 500 nm in size. In one embodiment, the grains have a mean grain size in a range of 10-300 nm. In one embodiment, the grains have a mean size of around 200 nm. Typically, the grains have random orientations. Further, grains may include 5-50 nm size (e.g., diameter or width) nanodot inclusions within the grains. As discussed above, such nanostructured materials may provide a relatively high power factor at elevated temperature (e.g., 450-900° C., such as 600-800° C.) with low thermal conductivity. Because of this low thermal conductivity, even when the TEG modules are located upstream of and/or are co-located with the heat exchanger between the hot burner gas and the boiler water, sufficient heat remains in the hot burner gas to efficiently heat the boiler water. In embodiments, the TEG modules located upstream of and/or co-located with the boiler heat exchanger (i.e., heat exchange region 206 in FIG. 2, which corresponds to the schematic heat exchanger 112 of FIG. 1A) generate at least 100% of the electric power consumed by the boiler during steady state operation. One or more additional TEG modules may be provided downstream of the heat exchanger (i.e., downstream or lower-temperature TEG modules) and may generate additional electric power from the waste heat of the burner exhaust. In some embodiments, the higher-temperature TEG modules located upstream of and/or co-located with the boiler heat exchanger modules may generate less than 100% of the total power requirements of the boiler, such as about 75%, 85%, 95%, or 99% of the total power requirements of the boiler, and the balance may be generated by the downstream or lower-temperature TEG modules.

The foregoing method descriptions are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not necessarily intended to limit the order of the steps; these words may be used to guide the reader through the description of the methods. Further, any reference to claim elements in the singular, for example, using the articles “a,” “an” or “the” is not to be construed as limiting the element to the singular.

Further, any step or component of any embodiment described herein can be used in any other embodiment.

The preceding description of the disclosed aspects is provided to enable any person skilled in the art to make or use the present invention. Various modifications to these aspects will be readily apparent to those skilled in the art, and the generic principles defined herein may be applied to other aspects without departing from the scope of the invention. Thus, the present invention is not intended to be limited to the aspects shown herein but is to be accorded the widest scope consistent with the principles and novel features disclosed herein.

What is claimed is:

1. A self-powered boiler, comprising:
a burner that is adapted to burn a fuel to produce a hot combustion product;
a hot combustion product conduit; and
a thermoelectric generator (TEG) system comprising a first side in thermal communication with the hot combustion product conduit and a second side in thermal communication with a lower temperature region of the boiler, and a plurality of thermoelectric converters disposed therebetween, the thermoelectric converters comprising a nano structured thermoelectric material, wherein electric power generated by the TEG system is equal to or greater than a total electric power consumed by the boiler under steady state operating conditions.

2. The boiler of claim 1, wherein the nano structured thermoelectric material comprises grains having at least one of a median grain size and a mean grain size less than one micron.

3. The boiler of claim 1, further comprising:
an electrical connection between the electrical output of the TEG system and at least one electrical component of the boiler.

4. The boiler of claim 1, wherein the nano structured thermoelectric material comprises a half-Heusler material.

5. The boiler of claim 1, wherein the thermoelectric converters are disposed on an outer surface of the hot combustion product conduit.

6. The boiler of claim 5, further comprising a plurality of heat exchange elements within the hot combustion product conduit and thermally coupled to the first side of the TEG system.

7. The boiler of claim 6, wherein the heat exchange elements comprise plate elements.

8. The boiler of claim 6, wherein the heat exchange elements comprise pin- and/or plate-type fin elements, wherein a packing fraction of the fins increases in the hot combustion product conduit along a direction away from the burner.

9. The boiler of claim 1, wherein the second side of the TEG system is in thermal communication with boiler water.

10. The boiler of claim 1, further comprising a heat exchanger for transferring heat from the hot combustion product to a fluid being heated.

11. The boiler of claim 10, wherein the fluid comprises water.

12. The boiler of claim 10, wherein the heat exchanger is located downstream of the TEG system with respect to the burner.

13. The boiler of claim 3, wherein the electrical component of the boiler comprises one or more of a control unit, a fan, a blower, an electrically actuated valve, an internal power supply, and a water pump of the boiler.

14. The boiler of claim 13, wherein the electrical component of the boiler comprises a water pump, a fan, at least one electrically actuated valve and a control unit.

15. The boiler of claim 1, the temperature at the first side of the TEG system is 400° C. or more.

16. The boiler of claim 15, wherein the temperature at the first side of the TEG system is greater than about 600° C.

17. The boiler of claim 15, wherein the temperature on the second side of the TEG system is less than about 200° C.

18. The boiler of claim 16, wherein the temperature on the second side of the TEG system is less than about 130° C.

19. The boiler of claim 1, wherein the TEG system produces between about 200 and about 500 W of electric power.

20. The boiler of claim 19, wherein the TEG system produces at least about 400 W of electric power.

21. The boiler of claim 1, wherein the boiler comprises a housing containing the boiler, the hot combustion product conduit, the TEG system, and a heat exchanger for transferring heat from the hot combustion product to a fluid being heated, wherein the TEG system is co-located with and/or located upstream of the heat exchanger with respect to the burner.

22. The boiler of claim 1, wherein the boiler comprises:
a burner unit containing the boiler, the hot combustion product conduit and the TEG system; and
a heat exchanger unit for transferring heat from the hot combustion product to a fluid being heated located downstream of the burner unit with respect to the flow of the hot combustion product from the burner.

23. The boiler of claim 1, wherein the TEG system comprises:
a heat exchanger located within the hot combustion product conduit such that at least a portion of the hot combustion product flows through the heat exchanger; and
a module having a first side and a second side opposite the first side, a cover comprising a thermally conductive material extending over the first side of the module and thermally coupled to the heat exchanger, and a plurality of interconnected pairs of first and second conductivity type thermoelectric elements extending between the first side and the second side of the module and thermally coupled to the cover.

24. The boiler of claim 23, wherein the heat exchanger comprises a plurality of heat exchange elements that extend from the cover into the hot combustion product conduit.

25. The boiler of claim 23, further comprising:
a cooling plate thermally coupled to the second side of the module, the module located between the cooling plate and an interior of the hot combustion conduit; and
a thermally insulating material that extends over at least one side surface of the module, the at least one side surface extending between the first and second surfaces of the module.

26. A method of operating a self-powered boiler, comprising:
burning a fuel to produce a hot combustion product;
flowing the hot combustion product in thermal contact with a first side of a thermoelectric generator (TEG) system comprising a nanostructured thermoelectric material; and
generating electrical power by the TEG system that is equal to or greater than a total electric power consumed by the boiler under steady state operating conditions.

27. The method of claim 26, wherein the nanostructured thermoelectric material comprises grains having at least one of a median grain size and a mean grain size less than one micron.

28. The method of claim 26, further comprising:
providing the electrical power to at least one electrical component of the boiler.

29. The method of claim 28, wherein the electrical component comprises a pump.

30. The method of claim 26, wherein the temperature at the first side of the TEG system is 400° C. or more.

31. The method of claim 30, wherein the temperature at the first side of the TEG system is greater than about 600° C.

32. The method of claim 30, wherein the temperature on the second side of the TEG system is less than about 200° C.

33. The method of claim 32, wherein the temperature on the second side of the TEG system is less than about 130° C.

34. The method of claim 26, wherein the TEG system generates between about 200 and about 500 W of electric power.

35. The method of claim 34, wherein the TEG system generates at least about 400 W of electric power.

36. The method of claim 26, wherein burning the fuel comprises burning the fuel in a burner and flowing the hot combustion product comprises flowing the hot combustion product in a conduit and the first side of the TEG system is in thermal communication with the conduit, the TEG system further comprising a second side in thermal communication with an area outside of the conduit having a lower temperature than the temperature within the conduit, and a plurality of elements of the nanostructured thermoelectric material disposed between the first side and the second side.

37. The method of claim 36, wherein the nanostructured thermoelectric material comprises a half-Heusler material.

38. The method of claim 36, wherein flowing the hot combustion product comprises flowing the hot combustion product in contact with a plurality of heat exchange elements located in the conduit and thermally coupled to the first side of the TEG system.

39. The method of claim 26, further comprising:
transferring heat from the hot combustion product to a fluid being heated.

40. The method of claim 39, wherein the fluid comprises water.

41. The method of claim 39, wherein the heat from the hot combustion product is transferred to the fluid being heated after flowing the hot combustion product in thermal contact with the first side of the TEG system.
